(19) United States
(12) Patent Application Publication
(10) Pub. No.: US 2026/0016531 A1
(43) Pub. Date: Jan. 15, 2026

(54) THERMOELECTRIC TEMPERATURE CONTROLLER FOR A TESTER AND METHODS OF OPERATING THE SAME

(71) Applicant: Taiwan Semiconductor Manufacturing Company Limited, Hsinchu (TW)

(72) Inventors: Ming-Hsuan Chang, Hsinchu City (TW); Yuan-Li Lin, Taichung City (TW); Sheng-Ming Yang, Kaohsiung City (TW); Kuo-Ming Lu, Hsinchu (TW)

(21) Appl. No.: 18/947,402

(22) Filed: Nov. 14, 2024

Related U.S. Application Data
(60) Provisional application No. 63/669,332, filed on Jul. 10, 2024.

(51) Int. Cl. G01R 31/28

(52) U.S. Cl. CPC G01R 31/2875; G01R 31/2865; G01R 31/2896

(57) ABSTRACT

A semiconductor testing apparatus includes: a chuck including a central cavity therethrough; a slow-response temperature control system including a thermal mass head that is mounted on the chuck and overlies the central cavity; a fast-response temperature control system including a thermoelectric module that is attached to the thermal mass head, is positioned within the central cavity, and is configured to be disposed on a device under test (DUT); a printed circuit board (PCB) underlying the chuck; and a test socket mounted on the printed circuit board and containing an array of pogo pins therein.

### RELATED APPLICATIONS

This application claims the benefit of priority from U.S. Provisional Application No. 63/669,332 entitled “Semiconductor Testing Apparatus and Cooling Method Patent Application” and filed on Jul. 10, 2024, the entire contents of which are incorporated herein by reference for all purposes.

### BACKGROUND

In the field of testing on semiconductor packages, managing the heat generated by integrated circuits during high-speed computing tests is a challenge. Related methods utilize a complex system involving a pusher, heater, and thermal mass head cooled by a heat exchanger to regulate the temperature of the integrated circuits. This multi-step cooling process introduces several inefficiencies and risks. The prolonged cooling path from the heat exchanger to the thermal mass head, through the heater, and finally to the pusher results in delayed thermal response, potentially exposing the integrated circuits to thermal damage. Additionally, the inability of the pusher to self-heat or self-cool necessitates extended periods to stabilize the temperature of the integrated circuits at the target settings, thereby reducing overall productivity. These limitations in related thermal management systems underscore the need for a more efficient and responsive cooling method to ensure the reliability of the semiconductor packages during testing.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic view of a semiconductor testing apparatus according to an embodiment of the present disclosure.

FIG. 2 is a vertical cross-sectional view of a thermal test assembly of the semiconductor testing apparatus prior to loading a device under test according to an embodiment of the present disclosure.

FIG. 3A is a vertical cross-sectional view of a first exemplary configuration of a thermoelectric module according to an embodiment of the present disclosure.

FIG. 3B is a vertical cross-sectional view of a second exemplary configuration of the thermoelectric module according to an embodiment of the present disclosure.

FIG. 3C is a vertical cross-sectional view of a third exemplary configuration of the thermoelectric module according to an embodiment of the present disclosure.

FIG. 3D is a vertical cross-sectional view of a fourth exemplary configuration of the thermoelectric module according to an embodiment of the present disclosure.

FIG. 4 is a vertical cross-sectional view of the thermal test assembly after loading a device under test according to an embodiment of the present disclosure.

FIG. 5 is a vertical cross-sectional view of the thermal test assembly after providing contact between electrical contact elements of the device under test and an array of pogo pins according to an embodiment of the present disclosure.

FIG. 6 is a flowchart that illustrates a set of processing steps for performing a thermal test according to an aspect of the present disclosure.

### DETAILED DESCRIPTION

The following disclosure provides many different embodiments, or examples, for implementing various features of the provided subject matter. Specific examples of components and arrangements are described below to simplify the present disclosure. These are merely examples, and are not intended to be limiting. Drawings are not drawn to scale. Elements with the same reference numerals refer to the same element, and are presumed to have the same material composition and the same thickness range unless expressly indicated otherwise. All features of an original embodiment are presumed to be present in any derived embodiment unless expressly disclosed otherwise. Thus, features described with reference to related embodiments in the drawings and/or in the specification provide support for features in an embodiment. Embodiments are expressly contemplated in which multiple instances of any described element are repeated unless expressly stated otherwise. Embodiments are expressly contemplated in which non-essential elements are omitted even if such embodiments are not expressly disclosed but are known in the art.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Various embodiments disclosed herein relate to a semiconductor testing apparatus that provides thermal management and reliable electrical testing for semiconductor packages. Related semiconductor testing systems often face challenges in maintaining consistent temperatures and ensuring stable electrical connections during high-speed tests, which may lead to inaccurate results and potential damage to the devices under test (DUT). Various embodiment semiconductor testing apparatuses described herein addresses these issues by using dual thermal control mechanisms in combination with precise alignment systems.

Various embodiment semiconductor testing apparatuses may include a chuck with a central cavity, a slow-response temperature control system with a thermal mass head mounted on the chuck, and a fast-response temperature control system featuring a thermoelectric module attached to the thermal mass head. The thermoelectric module may be positioned within the central cavity and is configured to be in direct or indirect contact with the DUT, facilitating efficient heat transfer. The thermal mass head may overlie the thermoelectric module and provides heat transfer between the thermoelectric module and a heat exchanger. Various embodiment semiconductor testing apparatuses may also comprise a printed circuit board (PCB) underlying the chuck and a test socket mounted on the PCB, containing an array of pogo pins for electrical connections. To improve the functionality and reliability of the testing process, the various embodiment semiconductor testing apparatuses may include a mounting base with a central opening that houses the test socket and a guiding mechanism for aligning the electrical contact elements of the DUT with the array of pogo pins. This guiding mechanism may include vertical protrusions and cavities that aim to ensure precise alignment, reducing the risk of misalignment during testing.

The apparatus also features a top enclosure, which includes a top cover plate and at least one sidewall that laterally encloses the chuck, thermal mass head, and thermoelectric module. This top enclosure, in combination with the mounting base, PCB, and test socket, defines an enclosed volume. To manage condensation within this enclosed volume, the various embodiment semiconductor testing apparatuses may be equipped with a gas circulation unit that supplies gas through a first opening and exhausts the gas through a second opening in the top enclosure. The various embodiment semiconductor testing apparatuses may also comprise a mounting bracket that secures the thermal mass head to the chuck. The thermal mass head includes a heat exchange fluid chamber filled with a heat exchange fluid, with the mounting bracket embedding portions of the supply and return lines for the heat exchange fluid. The slow-response temperature control system includes a heat exchanger that cools the heat exchange fluid and circulates heat exchange fluid through the supply and return lines, maintaining a stable temperature for the DUT.

Various embodiment methods of testing involve mounting the DUT to the chuck, aligning it with the pogo pins, and performing electrical tests by applying signals through the pogo pins. Various embodiment methods may also include steps for applying thermal interface materials, adjusting vertical distances for optimal contact, and using a guiding mechanism to ensure alignment. The various embodiment semiconductor testing apparatuses may integrate thermal control systems and alignment mechanisms, which may enhance the reliability and performance of semiconductor testing processes. These features address common issues in related testing systems and provide a solution for semiconductor manufacturing and testing requirements. The various aspects and embodiments of the methods and structures of the present disclosure are described with reference to accompanying drawings herebelow.

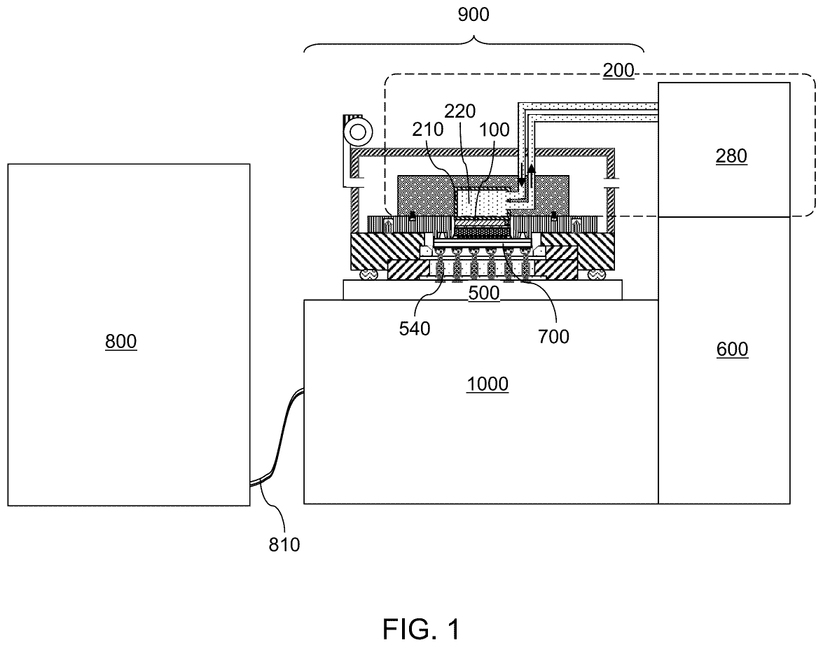

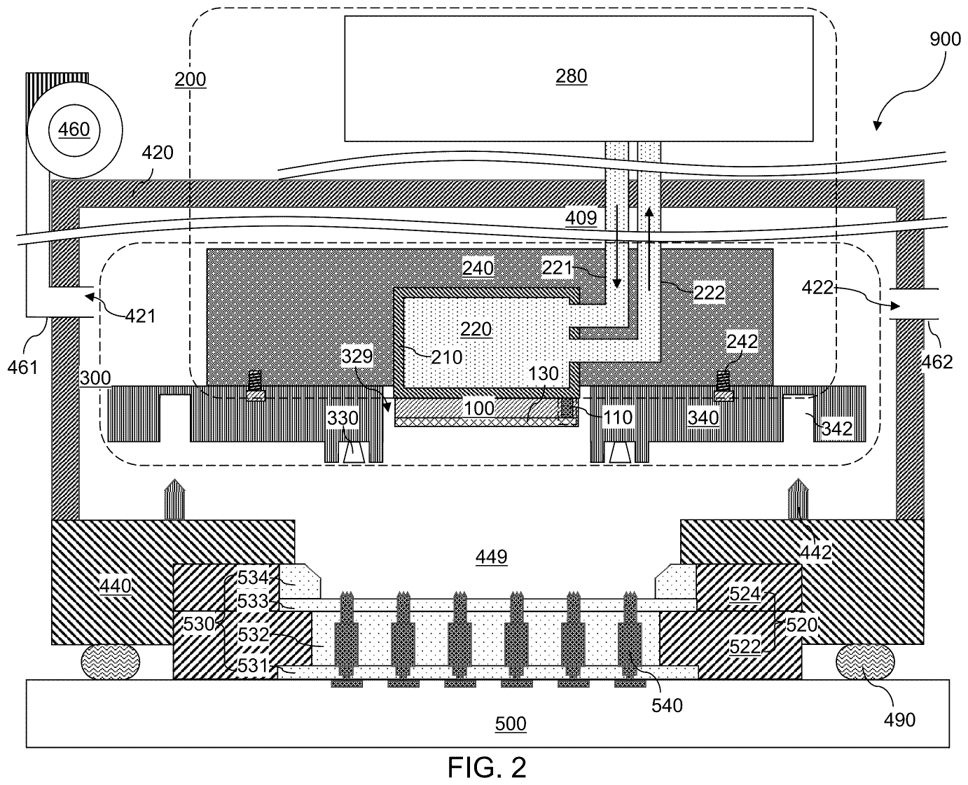

Referring to FIGS. 1 and 2, an exemplary semiconductor testing apparatus embodying an aspect of the present disclosure is illustrated. The exemplary semiconductor testing apparatus may include a tester electronics unit 800 including at least one computer and peripheral devices, a thermal test assembly 900 in communication with the tester electronics unit 800, for example, via signal and power cables 810, a tester mainframe 1000 configured to control movement of various moving parts within the thermal test assembly 900, and an optional device conveyer unit 600 configured to load and unload devices under test (DUT's) 700 to be tested on the thermal test assembly 900. The thermal test assembly 900 may include a printed circuit board (PCB) 500 containing an electronic circuitry configured for testing a device under test (DUT) 700. The PCB 500 may be mounted on the tester mainframe 1000. Generally, the PCB 500 may be customized based on the configuration of the DUT 700. Thus, upon selection of a DUT 700 to be tested, a suitable PCB 500 may be mounted on the tester mainframe 1000.

An array of pogo pins 540 may be mounted on the PCB 500. According to an aspect of the present disclosure, the thermal test assembly comprises dual cooling mechanisms. The dual cooling mechanisms comprise a fast-response temperature control system (100, 110, 800) and a slow-response temperature control system 200. The fast-response temperature control system comprises a thermoelectric module 100, a temperature sensor 110, and a portion of the tester electronics unit 800 configured to operate the thermoelectric module 100. The slow-response temperature control system 200 comprises a thermal mass head (210, 220), a heat exchanger 280, the temperature sensor 110, a portion of the tester electronics unit 800 configured to operate the thermal mass head (210, 220) and the heat exchanger 280, and peripheral components for operating the thermal mass head (210, 220) and the heat exchanger 280. The thermal mass head (210, 220) comprises a heat exchange fluid chamber 210 and a portion of a heat exchange fluid 220 therein. The temperature sensor 110 is a common component between the fast-response temperature control system (100, 110, 800) and the slow-response temperature control system 200.

The thermal test assembly 900 may be configured to perform a thermal test on the DUT 700. As used herein, a thermal test refers to a test performed at a temperature that is different from the room temperature (i.e., 20 degrees Celsius). Generally, a thermal test may be performed at any temperature in a range from-65 degrees Celsius to 225 degrees Celsius except 20 degrees Celsius. Typically, commercial-grade DUT's are tested in a temperature range from 0 degree Celsius to 70 degrees Celsius, industrial-grade DUT's are tested in a temperature range from-40 degree Celsius to 85 degrees Celsius, and military-grade DUT's are tested in a temperature range from-55 degrees Celsius to 125 degrees Celsius.

The thermal test assembly 900 may be configured to perform various types of thermal tests such as thermal cycling, thermal shock, and temperature forcing. Thermal cycling refers to a test in which the DUT 700 is repeatedly heated and cooled to simulate operational temperature changes and assess the DUT's ability to withstand thermal stress. Thermal shock refers to a test in which the DUT 700 is subjected to rapid temperature changes to evaluate its robustness and durability under sudden thermal transitions. Temperature forcing refers to a test in which the DUT 700 is maintained at a specific temperature, either above or below room temperature, to determine its performance and stability under controlled thermal conditions.

Additionally, the thermal test assembly 900 may be configured to perform a thermal test known as a burn-in test. During a burn-in test, the DUT 700 is operated under typical or extreme conditions to generate its own heat while being subjected to elevated temperatures in a controlled environment. This test aims to detect early failures and ensure the long-term reliability of the DUT 700 by identifying any components that may fail under extended use and high-stress conditions. Burn-in testing is advantageous for eliminating defective devices before they reach the customer, thereby improving the overall reliability of semiconductor products.

Failure to control temperature during a thermal test may have catastrophic results, including thermal runaway, device degradation, and inaccurate test outcomes. Inadequate temperature control may lead to excessive heating of the DUT 700, causing irreversible damage to its components and potentially leading to early failures when the device is deployed in real-world applications. Additionally, temperature fluctuations may introduce mechanical stress, leading to micro-cracks or delamination within the semiconductor package. These issues underscore the desire for advanced temperature control mechanisms that offer precise and rapid thermal management. Various embodiments disclosed herein may include dual cooling mechanisms to provide a solution that enhances temperature regulation during testing, addressing the limitations of existing systems. By integrating both a fast-response thermoelectric module and a slow-response thermal mass head with a heat exchange fluid chamber, the thermal test assembly 900 ensures stable and accurate thermal conditions, thereby improving the reliability and validity of thermal tests compared to traditional methods.

Referring to FIG. 2, the thermal test assembly 900 of the semiconductor testing apparatus of FIG. 1 is illustrated in detail. Generally, the semiconductor testing apparatus comprises a chuck 340 having a central cavity 329 therein, a slow-response temperature control system 200 comprising a thermal mass head (210, 220) that is mounted on the chuck 340 and overlies the central cavity 329, and a fast-response temperature control system (100, 110, 800) comprising a thermoelectric module 100 that is attached to the thermal mass head (210, 220).

It should be understood that “slow-response” temperature control system 200 is not designed to provide slower temperature control relative to previously known temperature control systems using a heat exchange fluid. The term “slow-response” means that a slow-response temperature control system has a slower response speed relative to a “fast-response” temperature control system. Generally, it may be expected that the “slow-response” temperature control system 200 may provide a temperature control response that is at least as fast as any other commercially available temperature control system that uses a heat exchange fluid. Further, it should be expected that the “fast-response” temperature control system (100, 110, 800) of the present disclosure may provide a temperature control response that is generally faster than any other commercially available temperature control system that uses a heat exchange fluid. This is because the operation of the “fast-response” temperature control system (100, 110, 800) of the present disclosure is based on electronic switching of the thermoelectric module 100 between a heat removal mode and a heat application mode through switching of the direction of the electrical current flow within the thermoelectric module 100. Since switching of an electronic circuitry may be done on a time scale of microseconds or nanoseconds, the response time of the fast-response temperature control system (100, 110, 800) is on the order of microseconds, and thus, provides a “fast” temperature response compared to previously known time scales for a response time for a temperature controller.

The central cavity 329 in the chuck 340 is large enough to accommodate a combination of the thermoelectric module 100 and the temperature sensor 110 therein. A thermal interface material layer 130 may be coated on the bottom surface of the combination of the thermoelectric module 100 and the temperature sensor 110. Alternatively, the thermal interface material layer 130 may be coated on a top surface of a DUT 700 (to be subsequently loaded), and the thermal interface material layer 130 may subsequently contact the bottom surface of the combination of the thermoelectric module 100 and the temperature sensor 110. A thermal interface material refers to a substance that is used to enhance thermal coupling between two surfaces, facilitating more efficient heat transfer between the components. Typically, thermal interface materials provide thermal conductivity in a range from 0.1 W/m. K to 2,000 W/m. K. Exemplary thermal interface materials include thermal grease, thermal pads, phase change materials, and liquid metal compounds.

In some embodiments, the semiconductor testing apparatus includes a thermal interface material layer 130 disposed between the thermoelectric module 100 and the DUT 700 to enhance thermal coupling. However, embodiments of the present disclosure are not limited to this configuration. For example, in embodiments where the DUT 700 has a flat top surface, the use of the thermal interface material 130 may be omitted. Additionally, the thermal conductivity of the thermal interface material may range from 0.1 W/m·K to 2,000 W/m· K, with materials such as graphene representing the upper end of this range.

In some embodiments, the semiconductor testing apparatus includes a temperature sensor 110 positioned within the thermoelectric module 100 to detect the temperature of the DUT 700. However, embodiments of the present disclosure are not limited to this configuration. In some embodiments, the temperature sensor 110 may be attached to the bottom surface, side, or any suitable location outside the thermoelectric module 100. Additionally, embodiments of the present disclosure are not limited to any specific method of temperature detection for the DUT 700. For example, in some embodiments, the temperature of the DUT 700 may be detected by reading temperature data from an embedded thermal sensor within the DUT 700 itself, without relying on the external temperature sensor 110.

In some embodiments, the semiconductor testing apparatus includes the thermoelectric module 100 replacing a traditional pusher to press the DUT 700 against the pogo pins 540. However, in embodiments in which the thermoelectric module 100 may lack sufficient strength to apply the required force, a cap may be added to the thermoelectric module 100 to prevent damage during the pressing process. It should be understood that the exemplary methods for enhancing the strength of the thermoelectric module 100 are not limited to the use of a cap. Any suitable method for preventing damage to the thermoelectric module 100 during pressing is included within the scope of the present disclosure.

In some embodiments, the semiconductor testing apparatus includes a temperature sensor 110 within the thermoelectric module 100 to detect the temperature of the DUT 700. In embodiments in which the thermoelectric module 100 lacks sufficient strength for pressing, a cap may be added to protect it from damage during operation. The temperature sensor 110 may be positioned within the cap or attached anywhere on the bottom surface of the thermoelectric module 100 or the cap. It should be noted that the methods discussed for IC temperature detection are not limited to these configurations. For example, in some embodiments, IC temperature may be detected by reading temperature data directly from the testing IC, without requiring the external temperature sensor 110.

The positioning of the thermoelectric module 100 within the central cavity 329 may depend on the die thickness of the DUT 700. In some embodiments, the thermoelectric module 100 is positioned in an upper portion of the central cavity 329 when the DUT 700 has a thicker die, while in embodiments where the DUT 700 has a thinner die, the thermoelectric module 100 may be positioned in a lower portion of the central cavity 329. This adjustment ensures optimal contact and temperature management based on the physical characteristics of the DUT 700.

In one embodiment, the thermal test assembly 900 of the semiconductor testing apparatus comprises a mounting bracket 240 to which the thermal mass head (210, 220) is mounted. The mounting bracket 240 overlies, and is fastened to, the chuck 340. In one embodiment, a spacing adjustment mechanism 242 may be provided between the mounting bracket 240 and the chuck 340 to enable small vertical movement of the mounting bracket 240 relative to the chuck 340. In embodiments that utilize the spacing adjustment mechanism 242, such a spacing adjustment mechanism 242 may be used to induce contact between an array of pogo pins 540 and electrical contact elements (such as solder material portions) of a DUT to be subsequently mounted at the bottom of the thermoelectric module 100. The combination of the chuck 340, the mounting bracket 240, the thermal mass head (210, 220), the thermoelectric module 100, and the optional thermally conductive material layer 130 is herein referred to as a chuck assembly 300.

As discussed above, the thermal mass head (210, 220) comprises a heat exchange fluid chamber 210 containing a heat exchange fluid 220. The mounting bracket 240 may embed a terminal portion of a supply line 221 configured to provide an influx of the heat exchange fluid 220 from the heat exchanger 280 to the heat exchange fluid chamber 210, and embeds a terminal portion of a return line 222 configured to provide a return path for the heat exchange fluid 220 from the heat exchange fluid 220 to the heat exchanger 280. The slow-response temperature control system 200 comprises a heat exchanger 280 configured to receive the heat exchange fluid 220 from the return line 222, to cool the heat exchange fluid 220, and to supply the heat exchange fluid 220 to the supply line 221.

Generally, the heat exchanger 280 operates by either removing heat from or providing heat to the heat exchange fluid 220 as it circulates through various components within the slow-response temperature control system 200. The heat exchanger 280 includes various components that facilitate this dual process of heat removal or heat application. First, a compressor within the heat exchanger 280 may compress the heat exchange fluid 220 (which may be a refrigerant) to increase the pressure and temperature of the heat exchange fluid 220. The pressurized heat exchange fluid 220 flows into a condenser, where it may dissipate heat to the surrounding ambient (which may include ambient air or externally supplied water), thereby cooling the heat exchange fluid 220 into a high-pressure liquid. Alternatively, in embodiments in which heating is required, the heat exchanger 280 may utilize the heat exchange fluid 220 to add heat to the system.

Next, the high-pressure liquid heat exchange fluid 220 passes through an expansion valve, which reduces the pressure and temperature of the heat exchange fluid 220 before entering an evaporator. In cooling mode, the evaporator allows the heat exchange fluid 220 to absorb heat from the thermal mass head (210, 220), causing the heat exchange fluid 220 to evaporate and cool the thermal mass head (210, 220). Conversely, in heating mode, the evaporator may facilitate the transfer of heat from the ambient to the heat exchange fluid 220. This heated heat exchange fluid 220 is then circulated back to the thermal mass head (210, 220) via the supply line 221, ensuring that the thermal mass head 210 maintains the desired temperature for the DUT 700 during testing.

The control system of the heat exchanger 280 may be provided within the heat exchanger 280 itself, or may be provided in the tester electronics unit 800, and operates to maintain precise temperature control of the heat exchange fluid 220 within the thermal mass head (210, 220), whether heating or cooling is desired. The control system of the heat exchanger 280 regulates the operation of the compressor, expansion valve, and other components based on temperature readings from sensors placed throughout the slow-response temperature control system 200. This control system provides rapid and precise temperature adjustments, allowing the thermal test assembly 900 to provide a stable and controlled thermal environment for accurate and reliable semiconductor testing. This level of control prevents overheating or excessive cooling, which may lead to inaccurate test results or damage to the DUT 700.

The fast-response temperature control system (100, 110, 800) comprises a thermoelectric module 100. The thermoelectric module 100 is positioned within the central cavity 329 and is attached to the bottom surface of the thermal mass head (210, 220). The thermoelectric module 100 is configured to be disposed on a device under test (DUT) 700 when the DUT 700 is attached to the chuck 340.

The thermoelectric module 100 operates on the Peltier effect. The Peltier effect refers to the phenomenon where heat is absorbed or released at the junctions of two different conductive materials when an electric current flows through them. This effect is utilized in thermoelectric modules to transfer heat between the DUT 700 and the thermal mass head (210, 220). In instances in which a direct electrical current passes through the thermoelectric module 100, one side of the module absorbs heat and becomes cooler, while the opposite side releases heat and becomes hotter. This enables the thermoelectric module 100 to either cool or heat the DUT 700 depending on the direction of the current. The heat transfer process involves the thermoelectric module 100 drawing heat from the DUT 700 and transferring it to the thermal mass head (210, 220) or vice versa, ensuring precise temperature control during testing.

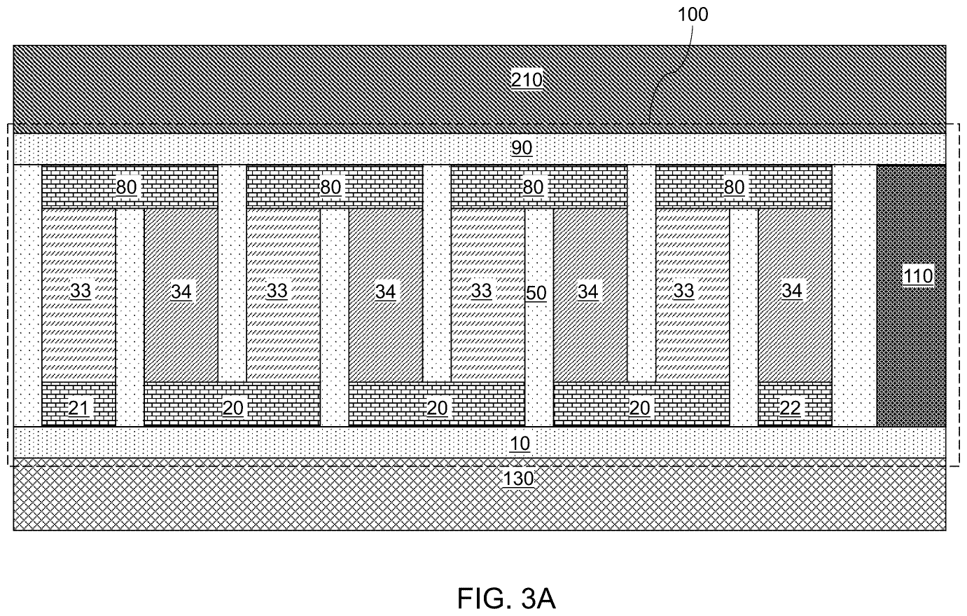

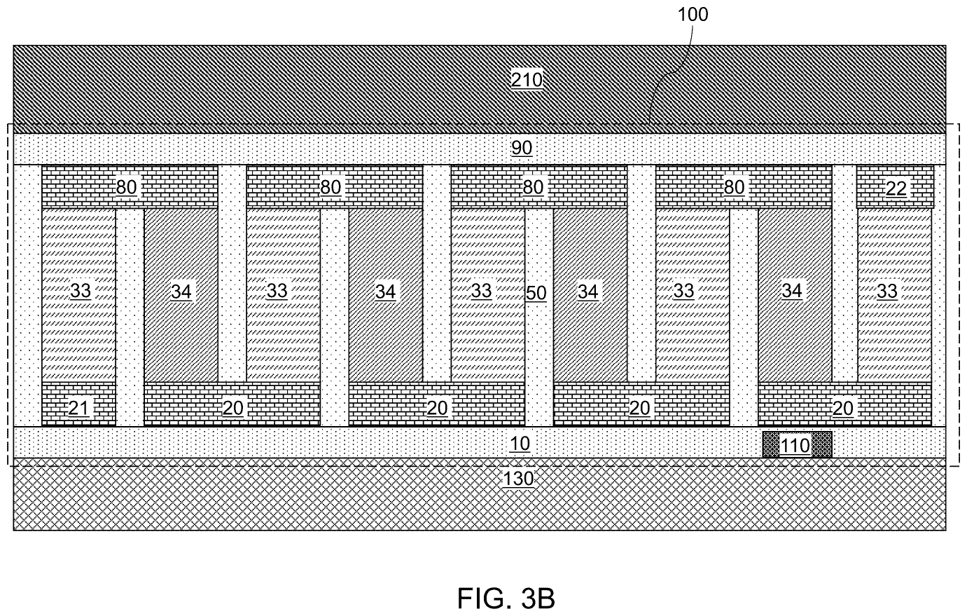

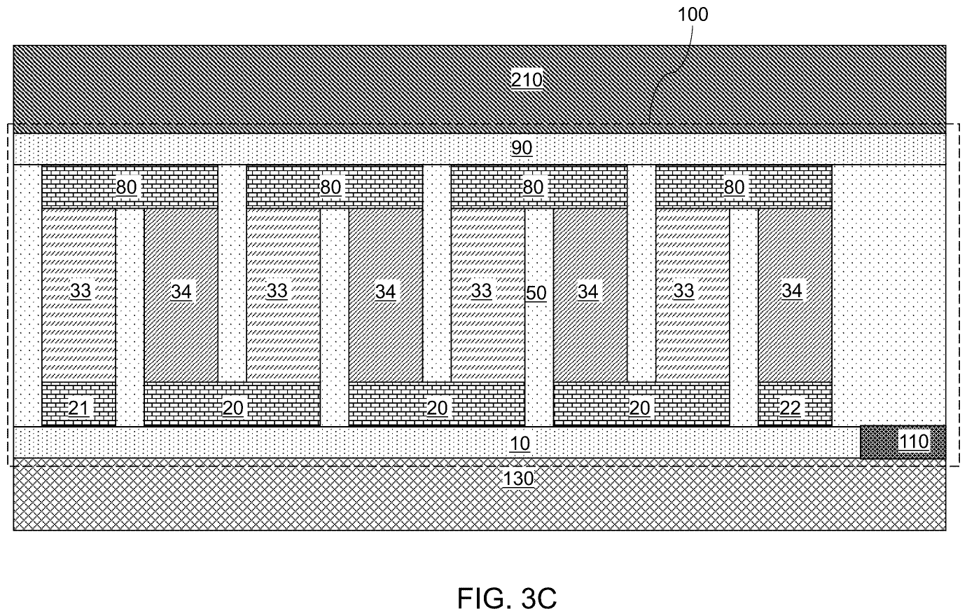

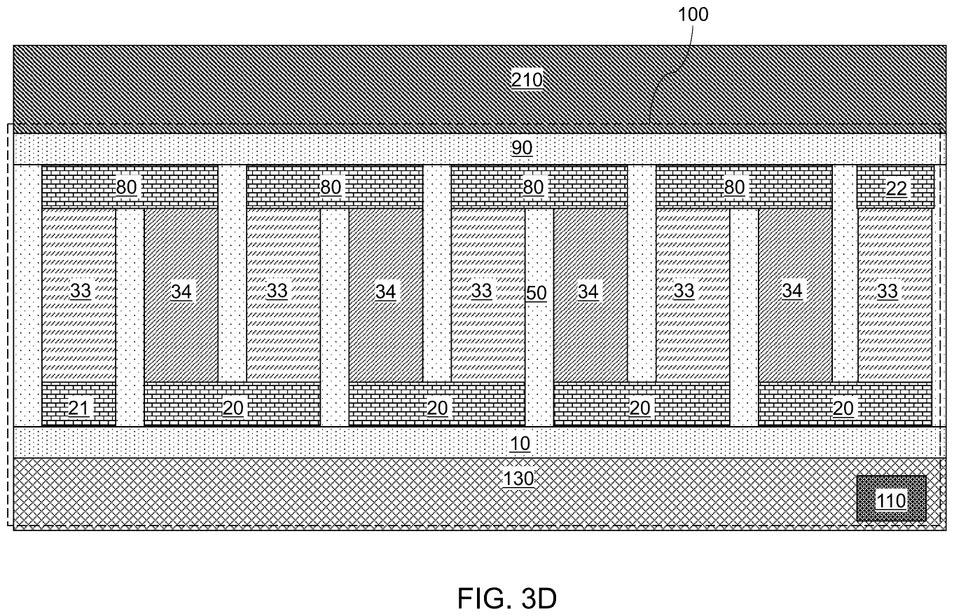

FIGS. 3A-3D illustrate various configurations of the thermoelectric module 100. Generally, the thermoelectric module 100 comprises p-doped semiconductor pillars 33 and n-doped semiconductor pillars 34. These pillars are arranged in an alternating pattern and connected electrically in series and thermally in parallel. In instances in which a direct electrical current flows through the pillars, electrons move through the n-doped semiconductor pillars 34 and holes move through the p-doped semiconductor pillars 33, causing heat to be absorbed at one junction and released at the other. This configuration allows the thermoelectric module 100 to transfer heat efficiently from the DUT 700 to the thermal mass head (210, 220) or from the thermal mass head (210, 220) to the DUT 700, depending on the direction of the current. The heat transfer is facilitated by upper and lower thermally conductive plates, which distribute the heat evenly across the surfaces of the DUT 700 and the thermal mass head (210, 220).

In one embodiment, the thermoelectric module 100 comprises an array of p-doped semiconductor pillars 33, an array of n-doped semiconductor pillars 34, upper connector plates 80 each connecting top ends of a respective first one of the p-doped semiconductor pillars 33 and a respective first one of the n-doped semiconductor pillars 34, and lower connector plates 20 each connecting bottom ends of a respective second one of the p-doped semiconductor pillars 33 and a respective second one of the n-doped semiconductor pillars 34, a lower thermally conductive plate 10, and an upper thermally conductive plate 90. The array of p-doped semiconductor pillars 33, the array of n-doped semiconductor pillars 34, the upper connector plates 80, and the lower connector plates 20 may be embedded within an insulating matrix 50. The array of p-doped semiconductor pillars 33 and the array of n-doped semiconductor pillars 34 may be embedded within an insulating matrix 50.

According to an aspect of the present disclosure, the thermoelectric module 100 comprises a temperature sensor 110. In one embodiment, the temperature sensor 110 may be embodied as a tip of a pair of thermocouple wires of which end portions are connected within the thermoelectric module 100. Alternatively, the temperature sensor 110 may comprise any other type of temperature sensor known in the art, including, but not limited to, electronic temperature sensors. Generally, the temperature sensor 110 may be disposed on, or within, the lower thermally conductive plate 10. In one embodiment, the temperature sensor 110 may be disposed between the lower thermally conductive plate 10 and the upper thermally conductive plate 90 as illustrated in FIG. 3A. In one embodiment, the temperature sensor 110 may be embedded within the lower thermally conductive plate 10 as illustrated in FIG. 3B. In one embodiment, the temperature sensor may be disposed on a side of the lower thermally conductive plate 10 or on a top surface of the lower thermally conductive plate 10 as illustrated in FIG. 3C. In one embodiment, the temperature sensor 110 may be embedded within the thermal interface material layer 130 as illustrated in FIG. 3D.

In a non-limiting illustrative example, the thermoelectric module 100, typically may comprise multiple p-doped semiconductor pillars 33 and multiple n-doped semiconductor pillars 34 made of materials such as doped bismuth telluride (Bi₂Te₃). These pillars are sandwiched between two thermally conductive plates that provide structural support and electrical insulation. The p-doped semiconductor pillars 33 and the n-doped semiconductor pillars 34 are connected electrically in series to form thermoelectric couples, with the pairs arranged in parallel to ensure uniform thermal distribution. In an illustrative example, a direct current path may comprise, from one end to another, a first end electrically conductive plate 21, at least one instance of a series connections of a p-doped semiconductor pillar 33, an upper connector plate 80, an n-doped semiconductor pillar 34, and a lower connector plate 20, and a second end electrically conductive plate 22. The number of instance(s) of the series connections of a p-doped semiconductor pillar 33, an upper connector plate 80, an n-doped semiconductor pillar 34, and a lower connector plate 20 may be in a range from 1 to 1,000,000, such as from 2⁴ to 2¹⁰, although a greater number may also be used.

In instances in which a direct current is flowed through an electrically conductive path within the thermoelectric module 100, electrons in the n-doped semiconductor pillars 34 move in the opposite direction of the electrical current flow, while holes in the p-doped semiconductor pillars 33 move in the direction of the electrical current flow. The movement of these charge carriers facilitates the transfer of heat. Specifically, electrons carry heat as they move through the n-doped semiconductor pillars 34, and holes carry heat as they move through the p-doped semiconductor pillars 33. Heat is absorbed at the junction where electrons enter the n-doped semiconductor pillars 34 and holes enter the p-doped semiconductor pillars 33, causing that side of the module to cool. Conversely, heat is released at the junction where electrons leave the n-doped semiconductor pillars 34 and holes leave the p-doped semiconductor pillars 33, causing that side of the module to heat. By reversing the direction of the electrical current, the locations of heat absorption and release may be swapped, thereby reversing the direction of heat flow. This capability allows the thermoelectric module 100 to effectively manage the thermal environment of the DUT 700 during testing by either heating or cooling as desired.

Referring back to FIG. 2, the thermal test assembly 900 of the semiconductor testing apparatus comprises a printed circuit board (PCB) 500 underlying the chuck 340. The PCB 500 may comprise a customized electrical circuit configured to enable testing of the DUT (such as a semiconductor package with solder balls as electrical contact elements).

A test socket 520 may be mounted on the printed circuit board 500. The test socket 520 may comprise a stack of a lower test socket plate 522 and an upper test socket plate 524. The test socket 520 contains an array of pogo pins 540 therein. The array of pogo pins 540 typically comprises spring-loaded pins designed for reliable electrical contact. These pogo pins are composed of a piston, spring, body, and cap, and are gold-plated to optimize conductivity and reduce contact resistance. The pitch of the array of pogo pins 540 may be selected to match the pitch of the electrical contact elements within the DUT to be subsequently mounted to the chuck 340. For example, the pitch of the array of pogo pins 540 may be in a range from 0.4 mm to 1.27 mm, although lesser and greater pitches may also be used. The total number of the pogo pins 540 within the array of pogo pins 540 may be in a range from 100 to 1,000, although lesser and greater numbers may also be used.

The array of pogo pins 540 may be attached to a dielectric laminate 530 to stabilize the relative positions amongst the pogo pins 540. The dielectric laminate 530 may comprise a stack of dielectric plates (531, 532, 533, 534). The array of pogo pins 540 may be affixed securely inside an opening in the test socket 520 through the dielectric laminate 530.

In one embodiment, the thermal test assembly 900 of the semiconductor testing apparatus may comprise a mounting base 440 having a central opening 449 therethrough. In this embodiment, the test socket 520 is located in a lower portion of the central opening 449. A mechanical actuator (not illustrated) may be provided within a volume enclosed by a combination of the top enclosure 420 and the mounting base 440.

In one embodiment, a device holder 330 may be provided on the chuck 340. The device holder 330 is configured to hold a device under test (DUT). The device holder 330 may have any configuration known in the art for holding a DUT. For example, the device holder 330 may comprise a clamping mechanism or a vacuum-based holder to securely position the DUT during testing

In one embodiment, the thermal test assembly 900 of the semiconductor testing apparatus may comprise a guiding mechanism (342, 442) for aligning electrical contact elements 790 of the DUT 700 with the array of pogo pins 540. In one embodiment, the guiding mechanism (342, 442) may comprises at least one vertical protrusion 442 located on one of the chuck 340 and the mounting base 440, and at least one vertically-extending cavity 342 located on another of the chuck 340 and the mounting base 440. The guiding mechanism (342, 442) provides lateral alignment between the chuck 340 and the mounting base 440 during vertical movement of the chuck 340 relative to the mounting base 440. Thus, the alignment between the DUT to be mounted and the array of pogo pins 540 may be maintained while the electrical contact structures DUT contacts the array of pogo pins 540 at a subsequent processing step.

According to an aspect of the present disclosure, the thermal test assembly 900 of the semiconductor testing apparatus may comprise a top enclosure 420 having a top cover plate that overlies the thermal mass head (210, 220) and a set of at least one sidewall that laterally encloses the chuck 340, the thermal mass head (210, 220), and the thermoelectric module 100. The assembly of the mounting base 440 and the top enclosure 420 presses against a printed circuit board (PCB) 500 with a seal ring 490 therebetween. An enclosed volume 409 may be formed, which is bounded by the top enclosure 420, the mounting base 440, the PCB 500, and the test socket 520. Generally, a combination of the top enclosure 420 and the mounting base 440 may be used to provide the enclosed volume 409. As discussed above, the mounting base 440 has a central opening 449 therethrough and laterally surrounding at least an upper portion of the test socket 520. The top enclosure 420 can be pressed against the mounting base 440 using any suitable mechanical means known in the art during formation of the thermal test assembly 900.

According to an aspect of the present disclosure, the enclosed volume 409 may be a sealed volume with openings (421, 422) for controlling the gas ambient therein. In one embodiment, the thermal test assembly 900 of the semiconductor testing apparatus may comprise a seal ring 490 configured to provide a vacuum seal by contacting an annular bottom surface segment of the mounting base 440 and by contacting an annular top surface segment of the PCB 500. In one embodiment, the seal ring 490 may be an elastic ring-shaped structure that laterally surrounds the array of pogo pins 540. The seal ring 490 provides an air-tight seal so that any gap (not illustrated) around the array of pogo pins 540 does not function as a pathway for air leaks during operation of the tester of the present disclosure.

In one embodiment, the top enclosure 420 comprises a first opening 421 and a second opening 422. In one embodiment, a gas may be supplied into the enclosed volume 409 through the first opening 421 in the top enclosure 420, and may be exhausted through the second opening 422. In one embodiment, the semiconductor testing apparatus comprises a gas circulation unit (460, 461, 462) configured to supply a gas into the enclosed volume 409 through the first opening 421 in the top enclosure 420, and to exhaust the gas through the second opening 422. The gas circulation unit (460, 461, 462) may comprise a fan 460 configured to induce forced flow of the gas into an inlet pipe 461 that is connected to the first opening 421. The gas circulation unit (460, 461, 462) may comprise an outlet tube 462 for guiding the exhaust flow of the gas out of the enclosed volume 409 through the second opening 422. The gas that is flowed into the enclosed volume 409 may be clean dry air (CDA) or any gas that is substantially free of moisture. The gas that is flowed into the enclosed volume 409 maintains the humidity of the gas ambient within the enclosed volume 409 at a low level to prevent condensation of moisture on the surfaces of various structural elements within the top enclosure 420.

The combination of the chuck 340, the mounting bracket 240, the thermal mass head (210, 220), and the thermoelectric module 100 may be configured to move together along a vertical direction by a mechanical actuator (not illustrated) which is provided within a volume enclosed by a combination of the top enclosure 420 and the mounting base 440. The movement of the chuck 340, the mounting bracket 240, the thermal mass head (210, 220), and the thermoelectric module 100 can be controlled by a movement control program that runs on the tester mainframe 1000. Generally, a sealable opening (not illustrated) may be provided on a sidewall of the top enclosure 420. The sealable opening may be embodied as a combination of an aperture in a sidewall of the top enclosure 420 and a slit valve that can seal the aperture upon closing, and can provide a path for transporting a device under test upon opening. Once the enclosed volume 409 is sealed, the enclosed volume 409 may remain sealed throughout the testing process.”

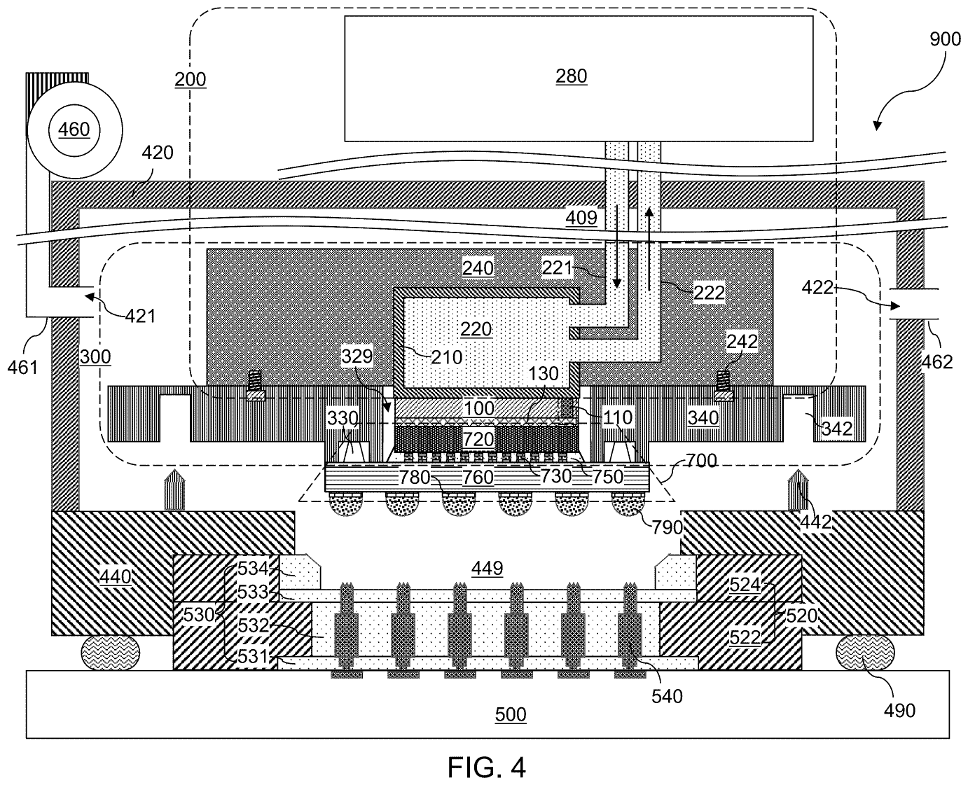

Referring to FIG. 4, the chuck assembly 300 may move to a lifted position, and the sealable opening on the sidewall of the top enclosure 420 may be opened. A device under test (DUT) 700 may be transported on a shuttle (not shown) through the sealable opening and into the volume enclosed by the combination of the top enclosure 420 and the mounting base 440. Once the DUT 700 is transported to a docking position, the chuck 340 may horizontally and then downwards to pick up the DUT 700. Once the shuttle exits the chamber, the chuck 340 moves horizontally to position the DUT 700 above the test socket 520. The DUT 700 may be attached to the chuck 340 using suitable means. For example, the DUT 700 may be attached to the chuck 340 using the device holder 330. A top surface of the DUT 700 may directly contact a bottom surface of the thermoelectric module 100, or a thermal interface material layer 130 may be used between the top surface of the DUT 700 and the bottom surface of the thermoelectric module 100. If the thermal interface material layer 130 is used, the thermal interface material layer 130 may be applied to the bottom surface of the thermoelectric module 100 prior to mounting the DUT 700, or may be applied to the DUT 700 prior to mounting the DUT 700.

Generally, a device under test (DUT) 700 may be mounted to the chuck 340 such that a top surface of the DUT 700 is in direct contact with, or is in indirect contact through a thermal interface material layer with, a bottom surface of the thermoelectric module 100. A thermal interface material may be applied on a bottom surface of the thermoelectric module 100 or on a top surface of the DUT 700. If a thermal interface material layer 130 is formed, the thermal interface material of the thermal interface material layer 130 is in direct contact with the bottom surface of the thermoelectric module 100 and with the top surface of the DUT 700.

In one embodiment, the electrical contact elements 790 of the DUT 700 comprises an array of solder material portions that faces the array of pogo pins 540 upon mounting the DUT 700 to the chuck 340. In an illustrative example, the DUT 700 may comprise a bonded assembly of a semiconductor die-containing unit 720, a packaging substrate 760, intra-package solder material portions 730 providing solder-mediated bonding between the semiconductor die-containing unit 720 and the packaging substrate 760, an underfill material portion 750, bonding pads 780 located on the packaging substrate 760, and solder material portions (which are electrical contact structures 790 for the pogo pins 540 and subsequently become solder joints upon bonding to a target bonding structure). The semiconductor-die containing unit 720 may be a semiconductor die, or a composite package containing at least one semiconductor die and optionally including at least one interposer.

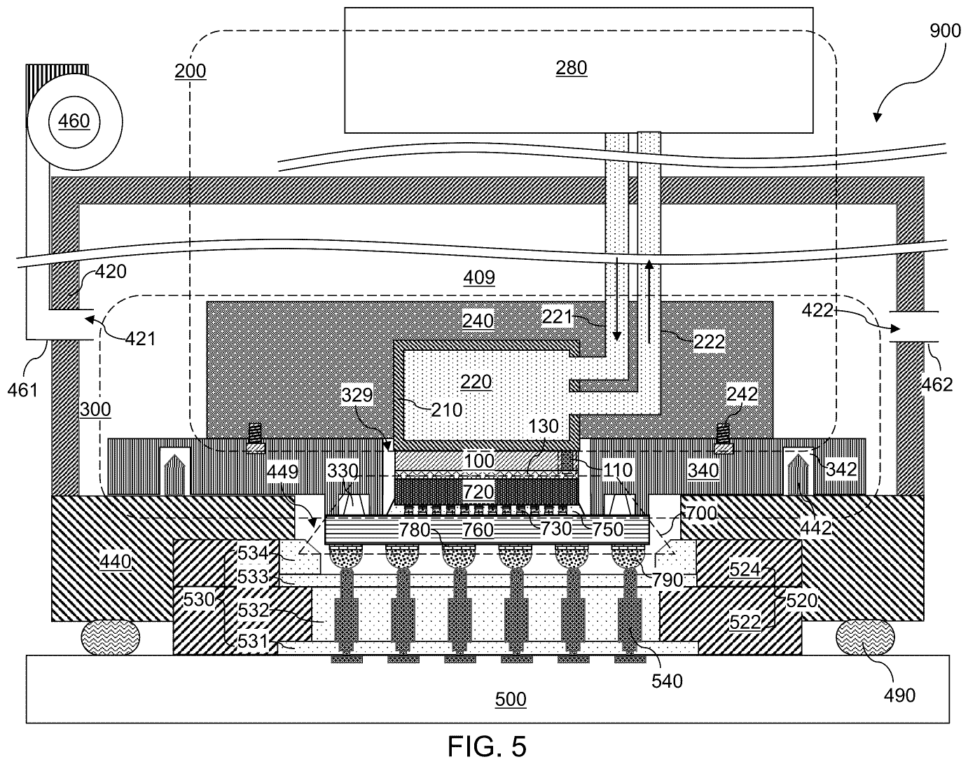

Referring to FIG. 5, the chuck assembly 300 with a DUT 700 thereupon may be lowered toward the combination of the PCB 500, the test socket 520, and the array of pogo pins 540 by actuating the mechanical actuator. Generally, the DUT 700 may be mounted to the chuck 340 using a device holder 330 while the chuck 340 is at a first vertical distance from the array of pogo pins 540. Subsequently, the chuck assembly 300 and the DUT 700 may be lowered to a test position by reducing the vertical distance between chuck 340 and the array of pogo pins 540, and by inducing direct contact between the DUT 700 and the array of pogo pins 540. In some embodiments, the array of pogo pins 540 may contact electrical contact elements 790 of the DUT 700. a seal ring 490 between the mounting base 440 and the PCB 500.

At a terminal step of lowering the chuck assembly 300 and the DUT 700, physical contact may be induced between the array of pogo pins 540 and the electrical contact elements 790 (such as the solder material portions) of the DUT 700 by inducing a small downward movement of the DUT 700. In embodiments in which a spacing adjustment mechanism 242 is present, the spacing adjustment mechanism 242 may be used to induce contact between an array of pogo pins 540 and electrical contact elements 790 (such as solder material portions) of the DUT 700. The vertical distance between the chuck 340 and the array of pogo pins 540 may be reduced to a second vertical distance that is less than the first vertical distance until the electrical contact elements 790 of the DUT 700 contact the array of pogo pins 540.

In one embodiment, the semiconductor testing apparatus comprises a guiding mechanism (342, 442) for aligning the electrical contact elements 790 of the DUT 700 with the array of pogo pins 540. In this embodiment, the vertical distance between the DUT 700 and the array of pogo pins 540 may be reduced while the guiding mechanism (342, 442) limits relative lateral movements of the DUT 700 relative to the array of pogo pins 540. The electrical contact elements 790 of the DUT 700 may be disposed on the array of pogo pins 540. In one embodiment, the electrical contact elements of the DUT 700 comprise an array of solder material portions that face the array of pogo pins 540 upon mounting the DUT 700 to the chuck 340. In this embodiment, the solder material portions may directly contact the tips of the array of pogo pins 540.

A gas for maintaining a condensation-free ambient within the enclosed volume 409 may be flowed into the enclosed volume 409 through the first opening 421 in the top enclosure 420, and may be exhausted through the second opening 422. The slow-response temperature control system 200 and the fast-response temperature control system (100, 110, 800) may be operated to provide a desired temperature setting for testing the DUT 700. Subsequently, an electrical test may be performed on the DUT 700 by applying test signals to the array of pogo pins 540.

According to an aspect of the present disclosure, the semiconductor testing apparatus of the present disclosure may improve the accuracy and efficiency of thermal tests on devices under test (DUT) 700. Related testing systems often face challenges in maintaining stable and precise temperatures, potentially leading to thermal damage to the DUT 700 and unreliable test results. The dual cooling mechanisms of the disclosed apparatus-comprising a fast-response temperature control system (100, 110, 800) and a slow-response temperature control system 200 with a thermal mass head (210, 220) and a heat exchange fluid chamber 210—address these issues by providing rapid and precise temperature adjustments.

The fast-response temperature control system (100, 110, 800), featuring a thermoelectric module 100, facilitates quick temperature changes due to the Peltier effect, ensuring that the DUT 700 reaches the desired test temperatures swiftly. This capability is essential for high-speed testing environments where traditional systems may not provide the necessary thermal transitions. Additionally, the slow-response temperature control system 200, which includes a thermal mass head (210, 220), a heat exchanger 280, and the temperature sensor 110, ensures long-term temperature stability and uniform heat distribution across the DUT 700. By combining these two systems, the disclosed apparatus minimizes thermal gradients and enhances the reliability of the thermal tests.

Furthermore, the apparatus includes a guiding mechanism (342, 442) for aligning the electrical contact elements 790 of the DUT 700 with the array of pogo pins 540 accurately, reducing the risk of misalignment and ensuring consistent electrical connections during testing. The enclosed volume 409, maintained by the top enclosure 420 and gas circulation unit (460, 461, 462), prevents condensation and maintains a stable testing environment, contributing to the accuracy of the test results. These features collectively offer improved performance over prior systems, providing reliable and efficient thermal management for semiconductor testing applications.

In some embodiments, the thermoelectric module 100 may lower the temperature of the DUT 700 to a point below the surrounding dew point, or even to sub-zero temperatures, to enhance cooling efficiency. This cooling may cause frost to accumulate around the thermoelectric module 100, potentially damaging the semiconductor testing apparatus and the DUT 700. However, in embodiments in which the thermoelectric module 100 does not need to reach such low temperatures due to reduced cooling capacity requirements, the frost formation issue may be mitigated, preventing potential damage to the testing apparatus and the DUT 700. In operations in which such frost formation or condensation does not pose an issue, flow of a gas for maintaining a condensation-free ambient may be omitted.

Some embodiments of the semiconductor testing apparatus may include a first opening 421 located on the top enclosure 420, configured to introduce dry air into the enclosed volume 409 to purge moisture and control the dew point within the enclosure, thereby preventing the formation of frost on the thermoelectric module 100. However, embodiments of the present disclosure are not limited to any specific location for injecting dry air. For example, the first opening 421 may be positioned at any location within the enclosed volume 409 without departing from the scope of the present disclosure. For example, a tube may be connected to the first opening 421 such that the outlet of the dry air may be any location within the enclosed volume 409.

In some embodiments, the semiconductor testing apparatus includes a first opening 421 that introduces dry air into the enclosed volume 409 to purge moisture, thereby controlling the dew point and preventing frost formation on the thermoelectric module 100. It should be understood that the exemplary methods discussed herein for preventing frost on the thermoelectric module 100 are not limited to the use of dry air. Any suitable method for avoiding frost formation is included within the scope of the present disclosure. For example, in some embodiments, frost prevention may be achieved by evacuating the enclosed volume 409 to create a vacuum, or by using a dehumidifier module (not illustrated). The placement of the dehumidifier module is not limited to any specific location, and the air inlet of the dehumidifier module may be positioned anywhere within the enclosed volume 409.

In some embodiments, the semiconductor testing apparatus includes a top enclosure 420 to isolate the thermoelectric module 100 from its surroundings through formation of an enclosed volume 409. However, embodiments of the present disclosure are not limited to this configuration. For example, in embodiments where high cooling capacity is not required and the thermoelectric module 100 does not need to cool the DUT 700 below the ambient dew point, frost formation may not occur. In such cases, the use of the top enclosure 420 for isolation may be unnecessary.

In some embodiments, the semiconductor testing apparatus includes a second opening 422 located on the top enclosure 420, allowing moisture to flow out and controlling the ambient pressure within the enclosed volume 409. It should be understood that the exemplary methods discussed for controlling the pressure inside the enclosed volume 409 are not limited to the use of a second opening 422. Any suitable method for pressure control within the enclosed volume 409 is included within the scope of the present disclosure. For example, a release valve, which also functions to control the pressure in the enclosed volume 409, may replace the second opening 422. The placement of the valve is not limited and may be positioned anywhere between the apparatus and the surrounding environment.

In some embodiments, the semiconductor testing apparatus includes a second opening 422 on the top enclosure 420 to allow moisture to flow out, thereby controlling the ambient pressure within the enclosed volume 409. However, the present disclosure is not limited to this configuration. For example, in some embodiments, the ambient pressure inside the enclosed volume 409 may still be controlled without the second opening 422 by allowing moisture to escape through any existing gaps in the testing apparatus.

In some embodiments, the semiconductor testing apparatus includes a seal ring 490 between the mounting base 440 and the PCB 500 to prevent moisture inflow, which could affect the ambient dew point within the enclosed volume 409. However, the present disclosure is not limited to this configuration. For example, in embodiments where the enclosed volume 409 does not include a second opening 422 or a release valve, moisture may be purged through the gap between the mounting base 440 and the PCB 500 to control the pressure within the enclosed volume 409. In one embodiment, the seal ring 490 may be omitted.

In some embodiments, the semiconductor testing apparatus includes a seal ring 490 positioned between the mounting base 440 and the PCB 500 to prevent the inflow of moisture, which could otherwise affect the ambient dew point within the enclosed volume 409. However, the present disclosure is not limited to this configuration. Any suitable method for preventing moisture from entering the enclosed volume 409 is included within the scope of the present disclosure.

In some embodiments, the seal ring 490 may be attached either to the bottom of the mounting base 440 or to the top surface of the PCB 500. It should be understood that the exemplary methods for placing the seal ring 490 discussed herein are not limited to these configurations. Any suitable method for positioning the seal ring 490 between the mounting base 440 and the PCB 500 is acceptable and included within the scope of the present disclosure.

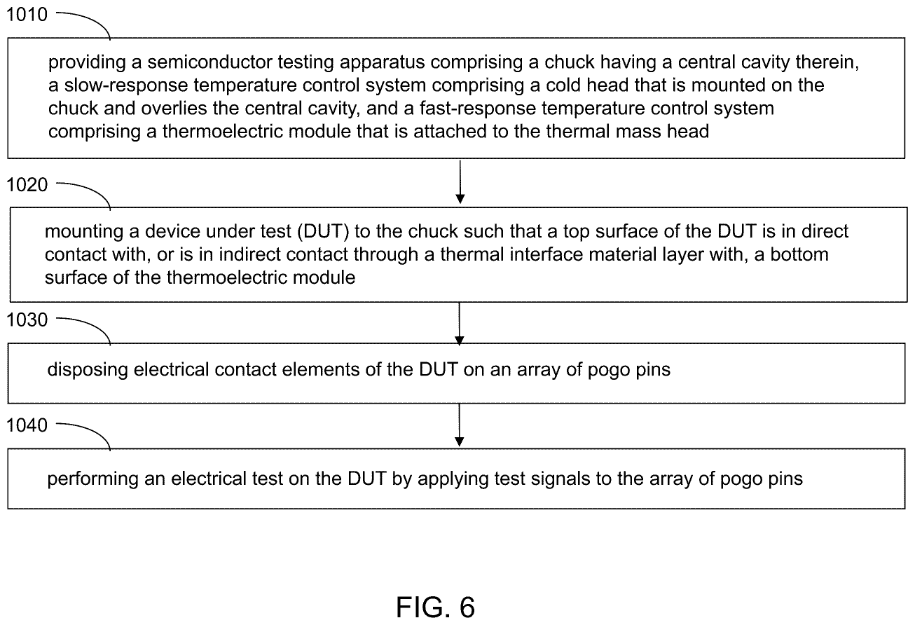

Referring to FIG. 6, a flowchart illustrates a set of processing steps for performing a thermal test according to an aspect of the present disclosure.

Referring to step 1010 and FIGS. 1-3, a semiconductor testing apparatus is provided, which comprises a chuck 340 having a central cavity 329 therein, a slow-response temperature control system 200 comprising a thermal mass head (210, 220) that is mounted on the chuck 340 and overlies the central cavity 329, and a fast-response temperature control system (100, 110, 800) comprising a thermoelectric module 100 that is attached to the thermal mass head (210, 220).

Referring to step 1020 and FIG. 4, a device under test (DUT) 700 may be mounted to the chuck 340 such that a top surface of the DUT 700 is in direct contact with, or is in indirect contact through a thermal interface material layer with, a bottom surface of the thermoelectric module 100.

Referring to step 1030 and FIG. 5, electrical contact elements 790 of the DUT 700 may be disposed on an array of pogo pins 540.

Referring to step 1040 and FIG. 5, an electrical test may be performed on the DUT 700 by applying test signals to the array of pogo pins 540.

Referring to all drawings and according to various embodiments of the present disclosure, a semiconductor testing apparatus is provided, which comprises: a chuck 340 comprising a central cavity 329 therethrough; a slow-response temperature control system 200 comprising a thermal mass head (210, 220) that is mounted on the chuck 340 and overlies the central cavity 329; a fast-response temperature control system (100, 110, 800) comprising a thermoelectric module 100 that is attached to the thermal mass head (210, 220), is positioned within the central cavity 329, and is configured to be disposed on a device under test (DUT) 700; a printed circuit board (PCB) 500 underlying the chuck 340; and a test socket 520 mounted on the printed circuit board 500 and containing an array of pogo pins 540 therein.

In one embodiment, the semiconductor testing apparatus comprises a mounting base 440 having a central opening 449 therethrough, wherein the test socket 520 is located in a lower portion of the central opening 449. In one embodiment the semiconductor testing apparatus comprises a guiding mechanism (342, 442) for aligning the electrical contact elements 790 of the DUT 700 with the array of pogo pins 540. In one embodiment, the guiding mechanism (342, 442) comprises at least one vertical protrusion 442 located on one of the chuck 340 and the mounting base 440, and at least one vertically-extending cavity 342 located on another of the chuck 340 and the mounting base 440.

In one embodiment, the semiconductor testing apparatus comprises a top enclosure 420 having a top cover plate that overlies the thermal mass head (210, 220) and a set of at least one sidewall that laterally encloses the chuck 340, the thermal mass head (210, 220), and the thermoelectric module 100, wherein an enclosed volume 409 is bounded by the top enclosure 420, the mounting base 440, the PCB 500, and the test socket 520. In one embodiment, the top enclosure 420 comprises a first opening 421 and a second opening 422; and the semiconductor testing apparatus comprises a gas circulation unit (460, 461, 462) configured to supply a gas into the enclosed volume 409 through the first opening 421 in the top enclosure 420, and to exhaust the gas through the second opening 422.

In one embodiment, the semiconductor testing apparatus comprises a mounting bracket 240 to which the thermal mass head (210, 220) is mounted, wherein the mounting bracket 240 overlies, and is fastened to, the chuck 340. In one embodiment, the thermal mass head (210, 220) comprises a heat exchange fluid chamber 210 containing a heat exchange fluid 220; the mounting bracket 240 embeds a portion of a supply line 221 configured to provide an influx of the heat exchange fluid 220, and a portion of a return line 222 configured to provide a return path for the heat exchange fluid 220; and the slow-response temperature control system 200 comprises a heat exchanger 280 configured to receive the heat exchange fluid 220 from the return line 222, to cool the heat exchange fluid 220, and to supply the heat exchange fluid 220 to the supply line 221.

According to another aspect of the present disclosure, a semiconductor testing apparatus is provided, which comprises: a chuck 340; a device holder located on the chuck 340 and configured to hold a device under test (DUT) 700; a thermal mass head (210, 220) mounted on a top surface of the chuck 340; a thermoelectric module 100 attached to a bottom surface of the thermal mass head (210, 220) and configured to be disposed on a top surface of the DUT 700; a printed circuit board (PCB) 500 underlying the chuck 340; and a test socket 520 mounted on the printed circuit board 500 and containing an array of pogo pins 540 therein.

In one embodiment, the semiconductor testing apparatus comprises: a mounting base 440 having a central opening 449 therethrough and laterally surrounding at least an upper portion of the test socket 520; and a top enclosure 420 having a top cover plate that overlies the thermal mass head (210, 220) and a set of at least one sidewall that laterally encloses the chuck 340, the thermal mass head (210, 220), and the thermoelectric module 100, wherein an enclosed volume 409 is bounded by the top enclosure 420, the mounting base 440, the PCB 500, and the test socket 520.

In one embodiment, the semiconductor testing apparatus comprises a seal ring 490 contacting an annular bottom surface segment of the mounting base 440 and contacting an annular top surface segment of the PCB 500 and laterally surrounding the array of pogo pins 540.

In one embodiment, the top enclosure 420 comprises a first opening 421 and a second opening 422; and the semiconductor testing apparatus comprises a gas circulation unit (460, 461, 462) configured to supply a gas into the enclosed volume 409 through the first opening 421 in the top enclosure 420, and to exhaust the gas through the second opening 422.

In one embodiment, the thermoelectric module 100 comprises an array of p-doped semiconductor pillars 33, an array of n-doped semiconductor pillars 34, upper connector plates 80 each connecting top ends of a respective first one of the p-doped semiconductor pillars 33 and a respective first one of the n-doped semiconductor pillars 34, and lower connector plates 20 each connecting bottom ends of a respective second one of the p-doped semiconductor pillars 33 and a respective second one of the n-doped semiconductor pillars 34, a lower thermally conductive plate 10, and an upper thermally conductive plate 90; and a temperature sensor 110 is disposed on, or within, the lower thermally conductive plate 10.

The foregoing outlines features of several embodiments so that those skilled in the art may better understand the aspects of the present disclosure. Each embodiment described using the term “comprises” also inherently discloses that the term “comprises” may be replaced with “consists essentially of” or with the term “consists of” in some embodiments, unless expressly disclosed otherwise herein. Whenever two or more elements are listed as alternatives in a same paragraph or in different paragraphs, a Markush group including a listing of the two or more elements may also be impliedly disclosed. Whenever the auxiliary verb “can” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein.

Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor testing apparatus comprising:
a chuck comprising a central cavity therethrough;
a slow-response temperature control system comprising a thermal mass head that is mounted on the chuck and overlies the central cavity;
a fast-response temperature control system comprising a thermoelectric module that is attached to the thermal mass head, is positioned within the central cavity, and is configured to be disposed on a device under test (DUT);
a printed circuit board (PCB) underlying the chuck; and
a test socket mounted on the printed circuit board and containing an array of pogo pins therein.

2. The semiconductor testing apparatus of claim 1, further comprising a mounting base having a central opening therethrough, wherein the test socket is located in a lower portion of the central opening.

3. The semiconductor testing apparatus of claim 2, further comprising a guiding mechanism for aligning electrical contact elements of the DUT with the array of pogo pins.

4. The semiconductor testing apparatus of claim 3, wherein the guiding mechanism comprises at least one vertical protrusion located on one of the chuck and the mounting base, and at least one vertically-extending cavity located on another of the chuck and the mounting base.

5. The semiconductor testing apparatus of claim 2, further comprising a top enclosure having a top cover plate that overlies the thermal mass head and a set of at least one sidewall that laterally encloses the chuck, the thermal mass head, and the thermoelectric module, wherein an enclosed volume is bounded by the top enclosure, the mounting base, the PCB, and the test socket.

6. The semiconductor testing apparatus of claim 5, wherein:
the top enclosure comprises a first opening and a second opening; and
the semiconductor testing apparatus comprises a gas circulation unit configured to supply a gas into the enclosed volume through the first opening in the top enclosure, and to exhaust the gas through the second opening.

7. The semiconductor testing apparatus of claim 1, further comprising a mounting bracket to which the thermal mass head is mounted, wherein the mounting bracket overlies, and is fastened to, the chuck.

8. The semiconductor testing apparatus of claim 7, wherein:
the thermal mass head comprises a heat exchange fluid chamber containing a heat exchange fluid;
the mounting bracket embeds a portion of a supply line configured to provide an influx of the heat exchange fluid, and a portion of a return line configured to provide a return path for the heat exchange fluid; and
the slow-response temperature control system comprises a heat exchanger configured to receive the heat exchange fluid from the return line, to cool the heat exchange fluid, and to supply the heat exchange fluid to the supply line.

9. A semiconductor testing apparatus comprising:
a chuck;
a device holder located on the chuck and configured to hold a device under test (DUT);
a thermal mass head mounted on a top surface of the chuck;
a thermoelectric module attached to a bottom surface of the thermal mass head and configured to be disposed on a top surface of the DUT;
a printed circuit board (PCB) underlying the chuck; and
a test socket mounted on the printed circuit board and containing an array of pogo pins therein.

10. The semiconductor testing apparatus of claim 9, further comprising:
a mounting base having a central opening therethrough and laterally surrounding at least an upper portion of the test socket; and
a top enclosure having a top cover plate that overlies the thermal mass head and a set of at least one sidewall that laterally encloses the chuck, the thermal mass head, and the thermoelectric module, wherein an enclosed volume is bounded by the top enclosure, the mounting base, the PCB, and the test socket.

11. The semiconductor testing apparatus of claim 10, further comprising a seal ring contacting an annular bottom surface segment of the mounting base and contacting an annular top surface segment of the PCB and laterally surrounding the array of pogo pins.

12. The semiconductor testing apparatus of claim 10, wherein:
the top enclosure comprises a first opening and a second opening; and
the semiconductor testing apparatus comprises a gas circulation unit configured to supply a gas into the enclosed volume through the first opening in the top enclosure, and to exhaust the gas through the second opening.

13. The semiconductor testing apparatus of claim 1, wherein:
the thermoelectric module comprises an array of p-doped semiconductor pillars, an array of n-doped semiconductor pillars, upper connector plates each connecting top ends of a respective first one of the p-doped semiconductor pillars and a respective first one of the n-doped semiconductor pillars, and lower connector plates each connecting bottom ends of a respective second one of the p-doped semiconductor pillars and a respective second one of the n-doped semiconductor pillars, a lower thermally conductive plate, and an upper thermally conductive plate; and
a temperature sensor is disposed on, or within, the lower thermally conductive plate.

14. A method of testing a semiconductor device, comprising:
providing a semiconductor testing apparatus comprising a chuck having a central cavity therein, a slow-response temperature control system comprising a thermal mass head that is mounted on the chuck and overlies the central cavity, and a fast-response temperature control system comprising a thermoelectric module that is attached to the thermal mass head;
mounting a device under test (DUT) to the chuck such that a top surface of the DUT is in direct contact with, or is in indirect contact through a thermal interface material layer with, a bottom surface of the thermoelectric module;
disposing electrical contact elements of the DUT on an array of pogo pins; and
performing an electrical test on the DUT by applying test signals to the array of pogo pins.

15. The method of claim 14, wherein the electrical contact elements of the DUT comprises an array of solder material portions that faces the array of pogo pins upon mounting the DUT to the chuck.

16. The method of claim 14, further comprising:
mounting the DUT to the chuck using a device holder while the chuck is at a first vertical distance from the array of pogo pins; and
reducing a vertical distance between the chuck and the array of pogo pins to a second vertical distance that is less than the first vertical distance until the electrical contact elements of the DUT contacts the array of pogo pins.

17. The method of claim 14, further comprising:
applying a thermal interface material on a bottom surface of the thermoelectric module or on a top surface of the DUT; and
mounting the DUT to the chuck such that the thermal interface material is in direct contact with the bottom surface of the thermoelectric module and with the top surface of the DUT.

18. The method of claim 14, wherein:
the semiconductor testing apparatus comprises a guiding mechanism for aligning the electrical contact elements of the DUT with the array of pogo pins; and
reducing a vertical distance between the DUT and the array of pogo pins while the guiding mechanism limits relative lateral movements of the DUT relative to the array of pogo pins.

19. The method of claim 14, wherein:
the semiconductor testing apparatus comprises a mounting base having an opening that contains the test socket;
the semiconductor testing apparatus comprises a top enclosure including a top cover plate and set of at least one sidewall; and
the method comprises forming an enclosed volume that is bounded by the top enclosure, the mounting base, the PCB, and the test socket.

20. The method of claim 19, wherein:
the top enclosure comprises a first opening and a second opening; and
the method further comprises supplying a gas into the enclosed volume through the first opening in the top enclosure and exhausting the gas through the second opening.
